(19) United States
(12) Patent Application Publication
(10) Pub. No.: US 2025/0329585 A1
(43) Pub. Date: Oct. 23, 2025

(54) INTERCONNECTION STRUCTURE AND METHOD FOR FORMING THE SAME

(71) Applicant: United Microelectronics Corp., Hsinchu (TW)

(72) Inventors: Chiu-Te Lee, Hsinchu County (TW); Shan-Shi Huang, Hsinchu City (TW); Shin-Hung Li, Nantou County (TW)

(73) Assignee: United Microelectronics Corp., Hsinchu (TW)

(21) Appl. No.: 18/679,362

(22) Filed: May 30, 2024

(30) Foreign Application Priority Data
Apr. 18, 2024 (TW) 113114476

(51) Int. Cl. H01L 21/768; H01L 23/522; H01L 23/532

(52) U.S. Cl. CPC H01L 21/76835; H01L 21/76829; H01L 21/76877; H01L 23/5226; H01L 23/53295

(57) ABSTRACT

Provided are an interconnection structure and a method for forming the same. The interconnection structure includes a first conductive line embedded in a first insulation layer, a second conductive line above the first conductive line, a second insulation layer disposed between the first conductive line and the second conductive line, and a dielectric pattern. The first conductive line extends in a first direction, and the second conductive line extends in a second direction crossing the first direction. The dielectric pattern is disposed in a portion of the second insulation layer where the first conductive line and the second conductive line cross each other in a top view.

### CROSS-REFERENCE TO RELATED APPLICATION

This application claims the priority benefit of Taiwan application serial no. 113114476, filed on Apr. 18, 2024. The entirety of the above-mentioned patent application is hereby incorporated by reference herein and made a part of this specification.

### BACKGROUND

### Technical Field

The disclosure relates to a semiconductor structure and a method for manufacturing the same, and more particularly, to an interconnection structure and a method for forming the same.

### Description of Related Art

As electronic devices move toward miniaturization in design and performance requirements from users for the electronic devices gradually increase, density and complexity of metal lines and metal through holes in interconnection structures also increase. In this way, a distance between the two adjacent metal lines applied with different voltages respectively will become smaller and smaller, so that time dependent dielectric breakdown (TDDB) of the electronic devices is insufficient to meet current or expected future requirements.

### SUMMARY

The disclosure provides an interconnection structure and a method for forming the same, in which a dielectric pattern is disposed in a portion of a second insulation layer where a first conductive line and a second conductive line cross each other in a top view, so that an electronic device may have good time dependent dielectric breakdown (TDDB).

An embodiment of the disclosure provides an interconnection structure, which includes a first conductive line embedded in a first insulation layer, a second conductive line above the first conductive line, a second insulation layer between the first conductive line and the second conductive line, and a dielectric pattern. The first conductive line extends in a first direction. The second conductive line extends in a second direction crossing the first direction. The dielectric pattern is disposed in a portion of the second insulation layer where the first conductive line and the second conductive line cross each other in a top view.

In some embodiments, a material of the dielectric pattern is different from a material of the second insulation layer.

In some embodiments, a dielectric constant of the dielectric pattern is greater than a dielectric constant of the second insulation layer.

In some embodiments, a dielectric constant of the dielectric pattern is greater than a dielectric constant of silicon oxide, and a dielectric constant of the second insulation layer is less than the dielectric constant of the silicon oxide.

In some embodiments, a voltage applied to the first conductive line is different from a voltage applied to the second conductive line.

In some embodiments, the interconnection structure further includes an etch stop layer and a cap layer. The etch stop layer is disposed between the first insulation layer and the second insulation layer. The cap layer is disposed between the etch stop layer and the second insulation layer. The cap layer covers a side surface of the dielectric pattern.

In some embodiments, the cap layer covers a top surface of the dielectric pattern.

In some embodiments, a thickness of the cap layer is less than a thickness of the dielectric pattern.

In some embodiments, the interconnection structure further includes a third conductive line embedded in the first insulation layer. The third conductive line is electrically connected to the second conductive line, and is electrically isolated from the first conductive line. The dielectric pattern includes an opening, and a conductive via electrically connecting the third conductive line to the second conductive line is disposed in the opening.

In some embodiments, a top surface of the dielectric pattern is in direct contact with the second conductive line.

In some embodiments, the dielectric pattern includes an island pattern disposed at a position where the first conductive line and the second conductive line overlap each other.

In some embodiments, the dielectric pattern includes a rectangular pattern elongated in the second direction.

An embodiment of the disclosure provides a method for forming an interconnection structure, which includes the following steps. A first conductive line extending in a first direction and embedded in a first insulation layer is formed. A dielectric pattern is formed on the first insulation layer. A second insulation layer covering the dielectric pattern is formed on the first insulation layer. A second conductive line extending in a second direction crossing the first direction is formed on the second insulation layer. The dielectric pattern is formed in a portion of the second insulation layer where the first conductive line and the second conductive line cross each other in a top view.

In some embodiments, a dielectric constant of the dielectric pattern is greater than a dielectric constant of the second insulation layer.

In some embodiments, a voltage applied to the first conductive line is different from a voltage applied to the second conductive line.

In some embodiments, the method for forming the interconnection structure further includes the following. An etch stop layer is formed between the first insulation layer and the second insulation layer. A cap layer is formed between the etch stop layer and the second insulation layer. The cap layer covers a side surface of the dielectric pattern.

In some embodiments, the cap layer is formed to cover a top surface of the dielectric pattern.

In some embodiments, the method for forming the interconnection structure further includes the following. A third conductive line embedded in the first insulation layer is formed. The third conductive line is electrically connected to the second conductive line, and is electrically isolated from the first conductive line. The dielectric pattern includes an opening, and a conductive via electrically connecting the third conductive line to the second conductive line is disposed in the opening.

In some embodiments, a step of forming the second conductive line includes the following. A trench exposing a top surface of the dielectric pattern is formed in the second insulation layer. A via hole in the opening of the dielectric pattern is formed in the second insulation layer. A conductive material is filled in the trench and the via hole to form the second conductive line and the conductive via.

In some embodiments, the dielectric pattern is isolated from the second conductive line by the second insulation layer.

Based on the above, in the interconnection structure and the method for forming the same, the dielectric pattern is designed to be disposed in the portion of the second insulation layer where the first conductive line and the second conductive line cross each other in the top view, so that the electronic device may have good time dependent dielectric breakdown (TDDB).

### BRIEF DESCRIPTION OF THE DRAWINGS

FIGS. 1A to 1E are schematic cross-sectional views of a method for forming an interconnection structure according to the first embodiment of the disclosure.

FIG. 2 is a schematic top view of the interconnection structure according to the first embodiment of the disclosure.

FIGS. 3A to 3D are schematic cross-sectional views of a method for forming an interconnection structure according to the second embodiment of the disclosure.

FIG. 4 is a schematic top view of the interconnection structure according to the second embodiment of the disclosure.

### DETAILED DESCRIPTION OF DISCLOSED EMBODIMENTS

The present disclosure will now be described more fully with reference to the accompanying drawings. However, the disclosure can be embodied in various forms, and is not limited to the embodiments provided below. The thickness of the layers and regions in the drawings is enlarged for clarity's sake. The same reference numbers are used in the drawings and the description to refer to the same or like parts, and description of the same parts are not repeated in following paragraphs.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements.

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

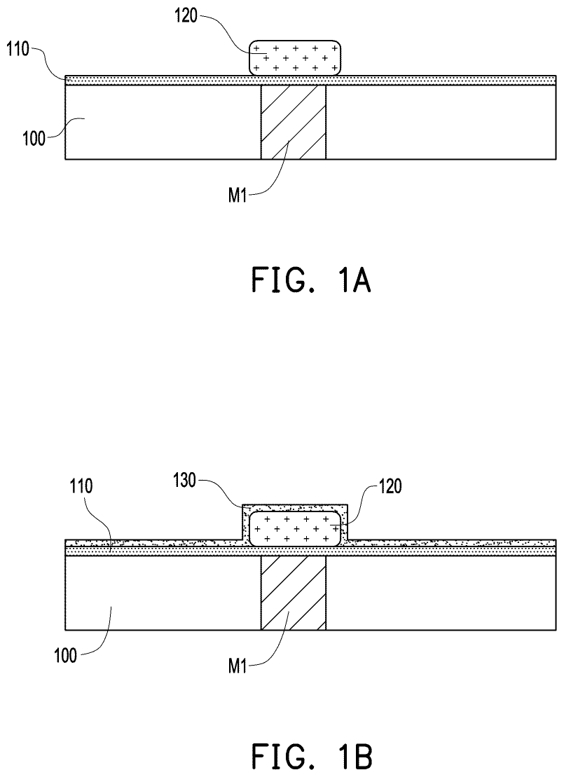

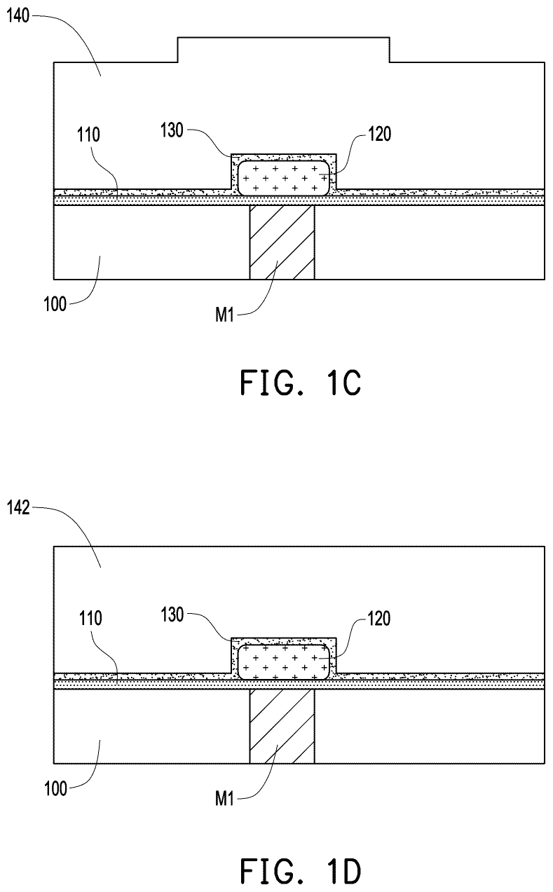

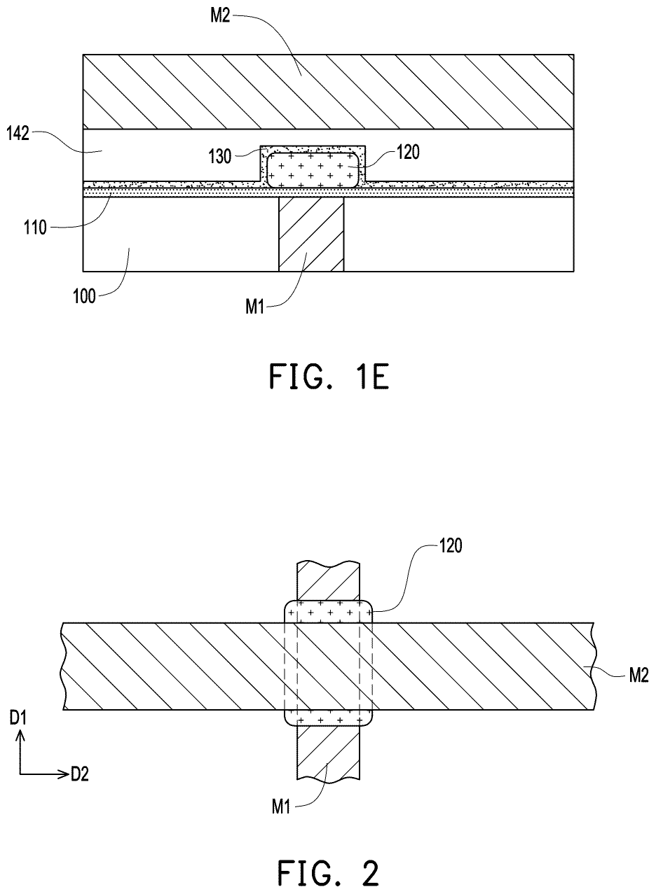

FIGS. 1A to 1E are schematic cross-sectional views of a method for forming an interconnection structure according to the first embodiment of the disclosure. FIG. 2 is a schematic top view of the interconnection structure according to the first embodiment of the disclosure.

First, referring to FIG. 1A, a first conductive line M1 extending in a first direction (a first direction D1 shown in FIG. 2) and embedded therein is formed in a first insulation layer 100. In some embodiments, the first insulation layer 100 may include a material with a dielectric constant less than a dielectric constant of silicon oxide (e.g., about 3.9). In other embodiments, the first insulation layer 100 may include an ultra-low-k (ULK) dielectric material with a dielectric constant less than about 2.6. The first conductive line M1 may include a conductive material such as metal or metal nitride. For example, the metal may include metallic materials such as aluminum (Al) or tungsten (W). The metal nitride may include metal nitride such as WN, TiSiN, WSiN, TiN, TaN, or a combination thereof. In some embodiments, the first insulation layer 100 may be an inter-metal dielectric (IMD) layer.

Next, a dielectric pattern 120 is formed on the first insulation layer 100. The dielectric pattern 120 may include a material with a dielectric constant greater than a dielectric constant of the first insulation layer 100. In some embodiments, in a case where the first insulation layer 100 includes the material with the dielectric constant less than the dielectric constant of silicon oxide (e.g., about 3.9), the dielectric pattern 120 may include a high-k (HK) dielectric material with a dielectric constant greater than silicon oxide, such as HfO₂, TiO₂, HfZrO, Ta₂O₃, HfSiO₄, ZrO₂, ZrSiO₂, LaO, AlO, ZrO, TiO, Ta₂O₅, Y₂O₃, BaZrO, HfZrO, HfLaO, HfSiO, LaSiO, AlSiO, HfTaO, HfTiO, Al₂O₃, Si₃N₄,or SiON. In other embodiments, in a case where the first insulation layer 100 includes the ULK dielectric material with the dielectric constant less than about 2.6, a material with a dielectric constant greater than the ULK dielectric material such as tetraethyl orthosilicate (TEOS) may be adopted for the dielectric pattern 120.

In some embodiments, the dielectric pattern 120 may be formed by the following steps. First, an etch stop layer 110 is formed on the first insulation layer 100. In some embodiments, the etch stop layer 110 may include nitride such as silicon nitride (SiN) or silicon carbonitride (SiCN). Next, a dielectric material layer (not shown) is formed on the etch stop layer 110. Then, a patterning process is performed on the dielectric material layer to form the dielectric pattern 120. The etch stop layer 110 may be formed between the first insulation layer 100 and a second insulation layer 142 subsequently formed above the etch stop layer 110.

Then, referring to FIG. 1B, a cap layer 130 covering the dielectric pattern 120 is formed on the etch stop layer 110. The cap layer 130 may include a dielectric material such as TEOS. The cap layer 130 may be formed between the etch stop layer 110 and the second insulation layer 142 subsequently formed on the cap layer 130.

Next, referring to FIG. 1C, a second insulation material layer 140 covering the dielectric pattern 120 is formed on the cap layer 130. The second insulation material layer 140 may include a material with a dielectric constant less than a dielectric constant of the dielectric pattern 120. For example, the second insulation material layer 140 may include the material with the dielectric constant less than the dielectric constant of silicon oxide (e.g., about 3.9) or the ULK dielectric material with the dielectric constant less than 2.6. In some embodiments, the same material as the first insulation layer 100 may be adopted for the second insulation material layer 140.

Then, referring to FIG. 1D, a planarization process such as chemical mechanical polishing (CMP) is performed on the second insulation material layer 140 to form the second insulation layer 142. In some embodiments, the second insulation layer 142 may be the IMD layer.

After that, referring to FIG. 1E, a second conductive line M2 extending in a second direction (a second direction D2 shown in FIG. 2) is formed on the second insulation layer 142. The second direction D2 crosses the first direction D1. In some embodiments, the second direction D2 may be perpendicular to the first direction D1. The second conductive line M2 may include a conductive material such as metal or metal nitride. For example, the metal may include metallic materials such as aluminum (Al) or tungsten (W). The metal nitride may include metal nitride such as WN, TiSiN, WSiN, TiN, TaN, or a combination thereof. In some embodiments, a voltage applied to the first conductive line M1 is different from a voltage applied to the second conductive line M2.

In some embodiments, the second conductive line M2 may be formed by the following steps. First, a trench is formed in the second insulation layer 142. Then, the conductive material is filled in the trench to form the second conductive line M2. In this embodiment, as shown in FIG. 1E, the trench in which the second conductive line M2 is formed does not expose a top surface of the dielectric pattern 120, so the cap layer 130 covers the top surface and a side surface of the dielectric pattern 120. In this embodiment, the trench in which the second conductive line M2 is formed also does not expose the cap layer 130, so the dielectric pattern 120 and the second conductive line M2 may further be isolated from each other by the second insulation layer 142 therebetween. In some alternative embodiments, the trench in which the second conductive line M2 is formed may expose the top surface of the dielectric pattern 120, so that the cap layer 130 only covers the side surface of the dielectric pattern 120.

Referring to FIGS. 1E and 2, the dielectric pattern 120 is formed in a portion of the second insulation layer 142 where the first conductive line M1 and the second conductive line M2 cross each other in a top view, so that an electronic device may have good time dependent dielectric breakdown (TDDB) without adding additional conductive layers. For example, in order to avoid an issue of poor time dependent dielectric breakdown (TDDB) at a crossing position of the adjacent conductive layers (hereinafter referred to as a first horizontal wiring and a second horizontal wiring) that are respectively supplied with different voltages in the interconnection structure, the second horizontal wiring is usually disposed farther away from the first horizontal wiring, which will require formation of additional IMD layers and conductive layers. Therefore, the dielectric pattern 120 not only solves the issue of poor time dependent dielectric breakdown (TDDB) at the crossing position of the first horizontal wiring and the second horizontal wiring, but also does not require the second horizontal wiring to be formed farther away from the first horizontal wiring (that is, no additional IMD layer and conductive layer is required to be formed).

In this embodiment, the dielectric pattern 120 may include an island pattern disposed at a position where the first conductive line M1 and the second conductive line M2 overlap each other (as shown in FIG. 2).

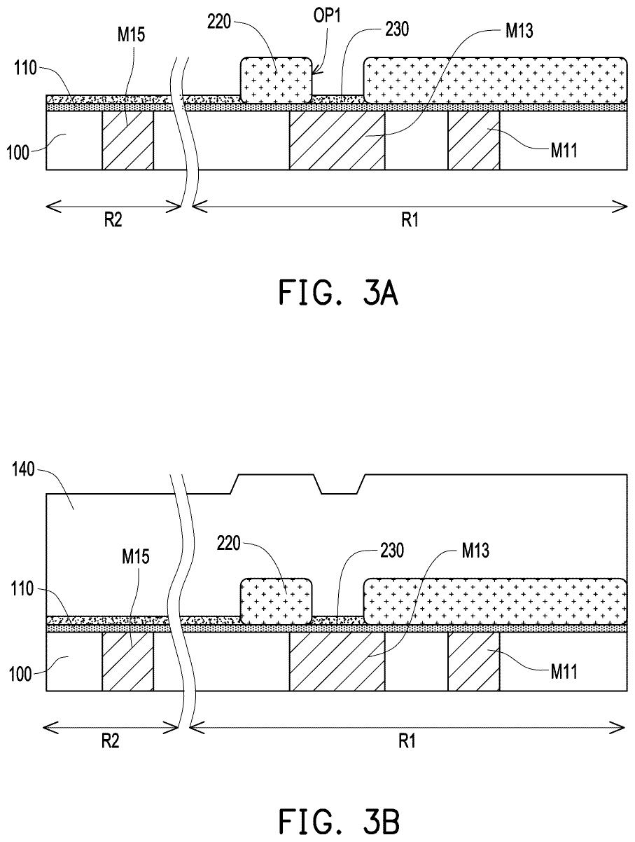

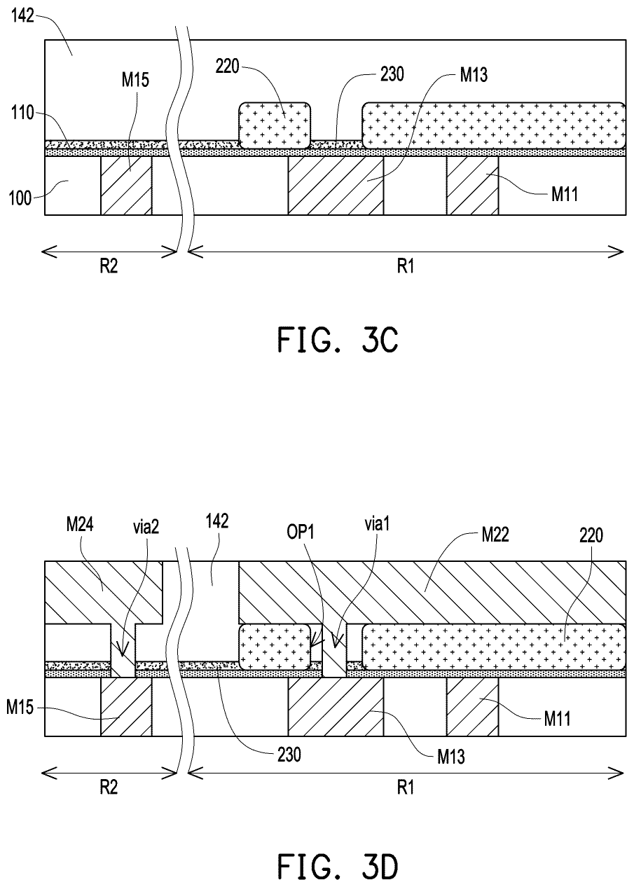

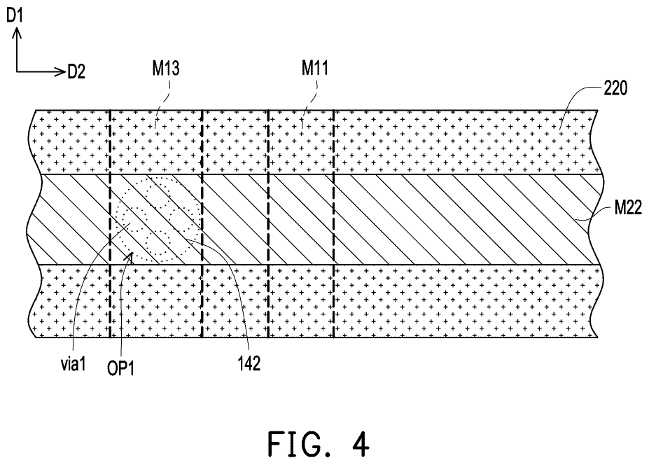

FIGS. 3A to 3D are schematic cross-sectional views of a method for forming an interconnection structure according to the second embodiment of the disclosure. FIG. 4 is a schematic top view of the interconnection structure according to the second embodiment of the disclosure. In this embodiment, the same or similar elements as those in the first embodiment will be denoted by the same or similar reference numerals, and will not be described again.

First, referring to FIG. 3A, a conductive line M11 and a conductive line M13 extending in the first direction (the first direction D1 shown in FIG. 4) and embedded in the first insulation layer 100 are formed. In this embodiment, the conductive line M11 and the conductive line M13 are formed in a first region R1. The first region R1 may, for example, be a region in which a medium-voltage semiconductor element is disposed. In some embodiments, as shown in FIG. 3A, the first insulation layer 100 is further formed with a conductive line M15 disposed in a second region R2 different from the first region R1. The second region R2 may, for example, be a region in which a low-voltage semiconductor element is disposed.

Next, a dielectric pattern 220 is formed on the first insulation layer 100. In this embodiment, the dielectric pattern 220 may include an opening OP1 corresponding to a position of the conductive line M13. In this embodiment, the dielectric pattern 220 may include a rectangular pattern elongated in the second direction (the second direction D2 as shown in FIG. 4). In some embodiments, the dielectric pattern 220 may be formed by the following steps. First, the etch stop layer 110 is formed on the first insulation layer 100. Next, the dielectric material layer (not shown) is formed on the etch stop layer 110. Then, the patterning process is performed on the dielectric material layer to form the dielectric pattern 220.

Then, a cap layer 230 is formed on the etch stop layer 110. In this embodiment, the cap layer 230 is formed on a top surface of the etch stop layer 110 and covers a bottom side surface of the dielectric pattern 220 adjacent to the etch stop layer 110. In some alternative embodiments, the cap layer 230 may also be formed on a top surface and a side surface of the dielectric pattern 220.

Then, referring to FIG. 3B, the second insulation material layer 140 covering the dielectric pattern 220 is formed on the cap layer 230.

Then, referring to FIG. 3C, the planarization process such as chemical mechanical polishing (CMP) is performed on the second insulation material layer 140 to form the second insulation layer 142.

After that, referring to FIGS. 3D and 4, a conductive line M22 extending in the second direction D2 is formed on the second insulation layer 142. In some embodiments, as shown in FIG. 3D, the second insulation layer 142 is further formed with a conductive line M24 disposed in the second region R2. In this embodiment, the conductive line M13 is electrically connected to the conductive line M22, and is electrically isolated from the conductive line M11. In this embodiment, the conductive line M13 is electrically connected to the conductive line M22 through a conductive via via1 disposed in the opening OP1 of the dielectric pattern 220.

In this embodiment, the conductive line M22 may be formed by the following steps. First, a trench exposing the top surface of the dielectric pattern 220 is formed in the second insulation layer 142. Next, a via hole disposed in the opening OP1 of the dielectric pattern 220 is formed in the second insulation layer 142. Then, the trench and the via hole are filled with the conductive material to form the conductive line M22 and the conductive via via1. In some embodiments, the conductive line M24 and a conductive via via2 electrically connecting the conductive line M24 to the conductive line M15 may be formed using the same or similar steps as above for forming the conductive line M22 and the conductive via via1. In this embodiment, FIG. 4 shows four conductive vias via1, but the number of conductive vias via1 is not limited thereto.

Referring to FIGS. 3D and 4, the dielectric pattern 220 is formed in the portion of the second insulation layer 142 where the conductive line M11 (i.e., the first conductive line) and the conductive line M22 (i.e., the second conductive line) cross each other in the top view, so that the electronic device may have good time dependent dielectric breakdown (TDDB) without adding the additional conductive layers. For example, in order to avoid the issue of poor time dependent dielectric breakdown (TDDB) at the crossing position of the adjacent conductive layers (hereinafter referred to as the first horizontal wiring and the second horizontal wiring) that are respectively supplied with different voltages in the interconnection structure, the second horizontal wiring is usually disposed farther away from the first horizontal wiring, which will require the formation of the additional IMD layers and conductive layers. Therefore, the dielectric pattern 220 not only solves the issue of poor time dependent dielectric breakdown (TDDB) at the crossing position of the first horizontal wiring and the second horizontal wiring, but also does not require the second horizontal wiring to be formed farther away from the first horizontal wiring (that is, no additional IMD layer and conductive layer is required to be formed).

Hereinafter, the interconnection structures in the first embodiment and the second embodiment of the disclosure will be described with reference to FIGS. 1E and 2 and/or FIGS. 3D and 4. The interconnection structures in the first embodiment and the second embodiment may be formed by the above method, but the disclosure is not limited thereto.

Referring to FIGS. 1E and 2 or FIGS. 3D and 4, the interconnection structure may include the conductive line M1 or M11 extending in the first direction D1 and embedded in the first insulation layer 100, the conductive line M2 or M22 extending above the conductive line M1 or M11 in the second direction D2, the second insulation layer 142 disposed between the conductive line M1 or M11 and the conductive line M2 or M22, and the dielectric pattern 120 or 220. The dielectric pattern 120 or 220 is disposed in the portion of the second insulation layer 142 where the conductive line M1 or M11 and the conductive line M2 or M22 cross each other in the top view. The voltage applied to the conductive line M1 or M11 is different from the voltage applied to the conductive line M2 or M22.

A material of the dielectric pattern 120 or 220 is different from a material of the second insulation layer 142. In this embodiment, the dielectric constant of the dielectric pattern 120 or 220 is greater than a dielectric constant of the second insulation layer 142. In this embodiment, the dielectric constant of the dielectric pattern 120 or 220 is greater than the dielectric constant of silicon oxide, and the dielectric constant of the second insulation layer 142 is less than the dielectric constant of silicon oxide.

As shown in FIGS. 1E and 2, the interconnection structure further includes the etch stop layer 110 and the cap layer 130. The etch stop layer 110 is disposed between the first insulation layer 100 and the second insulation layer 142. The cap layer 130 is disposed between the etch stop layer 110 and the second insulation layer 142. The cap layer 130 covers the side surface and the top surface of the dielectric pattern 120. In this embodiment, a thickness of the cap layer 130 is less than a thickness of the dielectric pattern 120. In this embodiment, the dielectric pattern 120 includes the island pattern disposed at the position where the conductive line M1 and the conductive line M2 overlap each other.

As shown in FIGS. 3D and 4, the interconnection structure further includes the conductive line M13 embedded in the first insulation layer 100. The conductive line M13 is electrically connected to the conductive line M22, and is electrically isolated from the conductive line M11. The dielectric pattern 220 includes the opening OP1, and the conductive via electrically connecting the conductive line M13 to the conductive line M22 is disposed in the opening OP1. In this embodiment, the top surface of the dielectric pattern 220 is in direct contact with the conductive line M22. In this embodiment, the dielectric pattern 220 includes the rectangular pattern elongated in the second direction D2.

Based on the above, in the interconnection structure and the method for forming the same in the above embodiments, the dielectric pattern is designed to be disposed in the portion of the second insulation layer where the first conductive line and the second conductive line cross each other in the top view, so that the electronic device may have good time dependent dielectric breakdown (TDDB).

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. An interconnection structure, comprising:
a first conductive line extending in a first direction and embedded in a first insulation layer;
a second conductive line extending above the first conductive line in a second direction, wherein the second direction crosses the first direction;
a second insulation layer disposed between the first conductive line and the second conductive line; and
a dielectric pattern disposed in a portion of the second insulation layer where the first conductive line and the second conductive line cross each other in a top view.

2. The interconnection structure according to claim 1, wherein a material of the dielectric pattern is different from a material of the second insulation layer.

3. The interconnection structure according to claim 1, wherein a dielectric constant of the dielectric pattern is greater than a dielectric constant of the second insulation layer.

4. The interconnection structure according to claim 1, wherein a dielectric constant of the dielectric pattern is greater than a dielectric constant of silicon oxide, and a dielectric constant of the second insulation layer is less than the dielectric constant of the silicon oxide.

5. The interconnection structure according to claim 1, wherein a voltage applied to the first conductive line is different from a voltage applied to the second conductive line.

6. The interconnection structure according to claim 1, further comprising:
an etch stop layer disposed between the first insulation layer and the second insulation layer; and
a cap layer disposed between the etch stop layer and the second insulation layer, wherein the cap layer covers a side surface of the dielectric pattern.

7. The interconnection structure according to claim 6, wherein the cap layer covers a top surface of the dielectric pattern.

8. The interconnection structure according to claim 6, wherein a thickness of the cap layer is less than a thickness of the dielectric pattern.

9. The interconnection structure according to claim 1, further comprising:
a third conductive line embedded in the first insulation layer, electrically connected to the second conductive line, and electrically isolated from the first conductive line,
wherein the dielectric pattern comprises an opening, and a conductive via electrically connecting the third conductive line to the second conductive line is disposed in the opening.

10. The interconnection structure according to claim 1, wherein a top surface of the dielectric pattern is in direct contact with the second conductive line.

11. The interconnection structure according to claim 1, wherein the dielectric pattern comprises an island pattern disposed at a position where the first conductive line and the second conductive line overlap each other.

12. The interconnection structure according to claim 1, wherein the dielectric pattern comprises a rectangular pattern elongated in the second direction.

13. A method for forming an interconnection structure, comprising:
forming a first conductive line extending in a first direction and embedded in a first insulation layer;
forming a dielectric pattern on the first insulation layer;
forming a second insulation layer covering the dielectric pattern on the first insulation layer; and
forming a second conductive line extending in a second direction on the second insulation layer, wherein the second direction crosses the first direction,
wherein the dielectric pattern is formed in a portion of the second insulation layer where the first conductive line and the second conductive line cross each other in a top view.

14. The method according to claim 13, wherein a dielectric constant of the dielectric pattern is greater than a dielectric constant of the second insulation layer.

15. The method according to claim 13, wherein a voltage applied to the first conductive line is different from a voltage applied to the second conductive line.

16. The method according to claim 13, further comprising:
forming an etch stop layer between the first insulation layer and the second insulation layer; and
forming a cap layer between the etch stop layer and the second insulation layer, wherein the cap layer covers a side surface of the dielectric pattern.

17. The method according to claim 16, wherein the cap layer is formed to cover a top surface of the dielectric pattern.

18. The method according to claim 13, further comprising:
forming a third conductive line embedded in the first insulation layer, wherein the third conductive line is electrically connected to the second conductive line and electrically isolated from the first conductive line,
wherein the dielectric pattern comprises an opening, and a conductive via electrically connecting the third conductive line to the second conductive line is disposed in the opening.

19. The method according to claim 18, wherein a step of forming the second conductive line comprises:
forming a trench exposing a top surface of the dielectric pattern in the second insulation layer;
forming a via hole in the opening of the dielectric pattern in the second insulation layer; and
filling a conductive material in the trench and the via hole to form the second conductive line and the conductive via.

20. The method according to claim 13, wherein the dielectric pattern is isolated from the second conductive line by the second insulation layer.
